(19) United States
(12) Patent Application Publication
(10) Pub. No.: US 2026/0353804 A1
(43) Pub. Date: Nov. 5, 2026

(54) DISPLAY PANEL, DETECTION METHOD THEREOF, DETECTION FIXTURE, AND DISPLAY DEVICE

(71) Applicant: Tianma Advanced Display Technology Institute (Xiamen) Co., Ltd., Xiamen (CN)

(72) Inventors: Zhenyu JIA, Xiamen (CN); Zhibo YANG, Xiamen (CN); Kerui XI, Xiamen (CN); Tianyi WU, Xiamen (CN); Bo ZHOU, Xiamen (CN); Xueling LI, Xiamen (CN); Yingteng ZHAI, Xiamen (CN); Xuhui PENG, Xiamen (CN)

(21) Appl. No.: 19/398,106

(22) Filed: Nov. 24, 2025

(30) Foreign Application Priority Data
Apr. 30, 2025 (CN) 202510564005.5

(51) Int. Cl. H10D 86/40; G09G 3/00; H10D 86/60

(52) U.S. Cl. CPC H10D 86/443; G09G 3/006; H10D 86/60; G09G 2320/0633; G09G 2320/064; G09G 2330/12

(57) ABSTRACT

Provided are a display panel and a detection method, a detection fixture and a display device. The display panel includes: a substrate including a first surface and a second surface opposite to each other, and a first side surface connected to and between the first surface and the second surface; a signal line arranged on the first surface; a connection electrode arranged on the first surface and electrically connected to the signal line; and a connection line electrically connected to the connection electrode and including a side trace portion arranged on the first side surface. The connection electrode includes a first connection electrode including a first region and a second region. The first connection electrode is connected to the connection line in the first region, and/or a position of the first connection electrode connected to the connection line is located in a non-central region of the first connection electrode.

### CROSS-REFERENCE TO RELATED APPLICATIONS

The present application claims priority to Chinese patent application No. 202510564005.5, filed on Apr. 30, 2025, which is hereby incorporated by reference in its entirety.

### TECHNICAL FIELD

The present disclosure relates to the field of display technologies and, in particular, to a display panel, a detection method thereof, a detection fixture and a display device.

### BACKGROUND

In a related design of a display panel, a signal line on the front surface of a substrate extends to a lower edge of the substrate and is connected to a connection electrode. The connection electrode overlaps with connection lines, and the connection lines extend from the front surface and the side surface of the substrate to the back surface of the substrate, so that the connection lines are electrically connected to a driving structure such as a driving chip or a printed circuit board. Such configuration facilitates realizing an ultra-narrow bezel or even a bezel-less design in the display panel.

In view of the problem of low yield in manufacturing the connection lines, it is usually necessary to inspect the connection lines for short circuits and open circuits before a display panel is shipped.

At present, generally, two short-circuited first test electrodes are additionally provided on the front surface of the substrate, the two first test electrodes are overlapped with a test connection line, respectively, and the two test connection lines extend to the back surface of the substrate and are electrically connected to two second test electrodes, respectively. During detection, the detection fixture probes on the second test electrode on the back surface to determine the connection status of the test connection lines by detecting parameters such as the contact resistance, thereby estimating the overall manufacturing quality of the connection lines. However, such a detection method has a poor detection effect, and thus significantly limits the detection of defective lines.

### SUMMARY

Embodiments of the present disclosure provides a display panel and a detection method thereof, a detection fixture and a display device, which are used for effectively improving the detection effect on the manufacturing quality of connection lines.

In a first aspect, an embodiment of the present disclosure provides a display panel, including a substrate, a signal line, a connection electrode, and a connection line.

The substrate includes a first surface and a second surface that are opposite to each other, and a first side surface connected to and between the first surface and the second surface.

The signal line is arranged on the first surface.

The connection electrode is arranged on the first surface and electrically connected to the signal line.

The connection line is electrically connected to the connection electrode and includes a side trace portion arranged on the first side surface.

The connection electrode includes a first connection electrode including a first region and a second region. The first connection electrode is connected to the connection line in the first region, and/or a position of the first connection electrode connected to the connection line is located in a non-middle region of the first connection electrode.

In a second aspect, based on the same inventive concept, an embodiment of the present disclosure further provides a method for detecting a display panel, which is applied to the above-mentioned display panel, including: providing a detection fixture, the detection fixture including a first detection point, a second detection point, a first probe electrically connected to the first detection point, and a second probe electrically connected to the second detection point; and placing the display panel with the front side facing upwards in the detection fixture, placing the first probe at a side of the first surface and in contact with the second region of the first connection electrode, placing the second probe at a side of the second surface and providing a detection voltage to the connection line, and determining a connection status of the connection line according to a resistance between the first detection point and the second detection point.

In a third aspect, based on the same inventive concept, an embodiment of the present disclosure further provides a detection fixture for detecting the above-mentioned display panel, including: a first detection point, a second detection point, a first probe electrically connected to a first detection point and a second probe electrically connected to a second detection point. The first probe is configured to contact the second region of the first connection electrode in the display panel, and the second probe is configured to apply a detection voltage to the connection line in the display panel.

In a fourth aspect, based on the same inventive concept, an embodiment of the present disclosure further provides a display device including the above-mentioned display panel.

The technical solutions provided in the embodiments of the present disclosure have the following beneficial effects.

In some embodiments of the present disclosure, the connection electrode includes a first connection electrode. Only a partial region (the first region) of the first connection electrode is configured overlap with the connection line, and another partial region (the second region) of the first connection electrode remains unoccupied. This unoccupied region is configured to provide a contact point for a probe when detecting the connection line. When detecting the connection status of the connection line, the probe is inserted into the second region of the first connection electrode, so as to detect the connection status of the connection line corresponding to the first connection electrode. Such configuration can realize independent detection on the connection lines, and accurately obtain the connection status of each connection line, so as to specifically remedy the connection line with connection problems, so that the display panel can have a better detection effect. Further, due to such configuration, the probe does not affect the connection line during the detection, thereby preventing the connection line from being pierced by the probe and thus from affecting the reliability of the connection of the connection line to the first connection electrode.

### BRIEF DESCRIPTION OF DRAWINGS

In order to better illustrate the technical solutions in embodiments of the present disclosure or the related art, the drawings used in the description of the embodiments will be briefly illustrated as follows. It should be noted that, the drawings described below are merely some, rather than all, of the embodiments of the present disclosure. Based on these drawings, those skilled in the art can obtain other drawings without any creative effort.

FIG. 1 is a schematic structural diagram of a display panel according to an embodiment of the present disclosure;

FIG. 2 is a schematic diagram of a front surface of a display panel according to an embodiment of the present disclosure;

FIG. 3 is a schematic diagram of a back surface of a display panel according to an embodiment of the present disclosure;

FIG. 4 is a schematic diagram of a detection of a display panel according to an embodiment of the present disclosure;

FIG. 5 is another schematic structural diagram of a display panel according to an embodiment of the present disclosure;

FIG. 6 is schematic diagram of a circuit structure of a pixel circuit according to an embodiment of the present disclosure;

FIG. 7 is a schematic structural diagram of a connection electrode according to an embodiment of the present disclosure;

FIG. 8 is another schematic structural diagram of a connection electrode according to an embodiment of the present disclosure;

FIG. 9 is another schematic structural diagram of a connection electrode according to an embodiment of the present disclosure;

FIG. 10 is another schematic structural diagram of a display panel according to an embodiment of the present disclosure;

FIG. 11 is another schematic diagram of a back surface of a display panel according to an embodiment of the present disclosure;

FIG. 12 is another schematic diagram of a back surface of a display panel according to an embodiment of the present disclosure;

FIG. 13 is another schematic diagram of a back surface of a display panel according to an embodiment of the present disclosure;

FIG. 14 is a top view of a first connection electrode according to an embodiment of the present disclosure;

FIG. 15 is a cross-sectional view taken along A1-A2 shown in FIG. 14;

FIG. 16 is a schematic cross-sectional view of a display panel according to an embodiment of the present disclosure;

FIG. 17 is another schematic structural diagram of a front surface of a display panel according to an embodiment of the present disclosure;

FIG. 18 is another schematic structural diagram of a display panel according to an embodiment of the present disclosure;

FIG. 19 is another schematic structural diagram of a connection electrode according to an embodiment of the present disclosure;

FIG. 20 is another schematic diagram of a back surface of a display panel according to an embodiment of the present disclosure;

FIG. 21 is a schematic structural diagram of a display device according to an embodiment of the present disclosure; and

FIG. 22 is another schematic structural diagram of a display device according to an embodiment of the present disclosure.

### DESCRIPTION OF EMBODIMENTS

In order to better understand technical solutions of the present disclosure, embodiments of the present disclosure are described in detail below in conjunction with the drawings.

It should be made clear that the embodiments described are only part of rather than all of the embodiments of the present disclosure. All other embodiments obtained by those skilled in the art without creative efforts according to the embodiments of the present disclosure shall fall within a scope of the present disclosure.

The terms used in the embodiments of the present disclosure are merely for the purpose of describing specific embodiments, but not intended to limit the present disclosure. Singular forms of “a/an”, “said” and “the” used in the embodiments of the present disclosure and the appended claims are also intended to include plural forms, unless explicitly indicating other meanings.

It should be understood that the term “and/or” used in the present disclosure represents an association relationship to describe associated objects, and can indicate three relationships. For example, A and/or B can indicate A alone, A and B, and B alone. Further, the character “/” herein generally denotes an “or” relationship between the associated objects on either side of the character.

An embodiment of the present disclosure provides a display panel. The display panel may be a light emitting diode (LED) display panel, an organic light emitting diode (OLED) display panel, or the like, such as a mini LED display panel or a micro LED display panel.

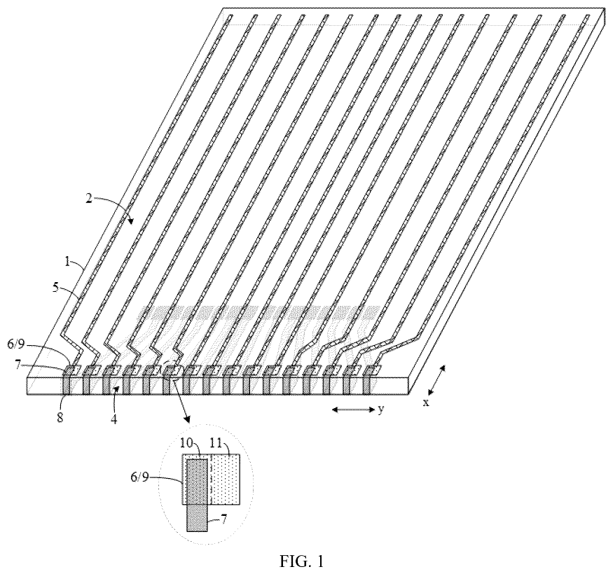

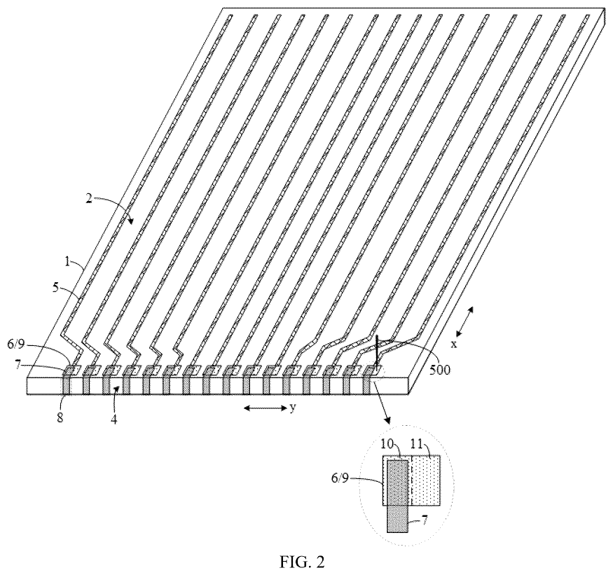

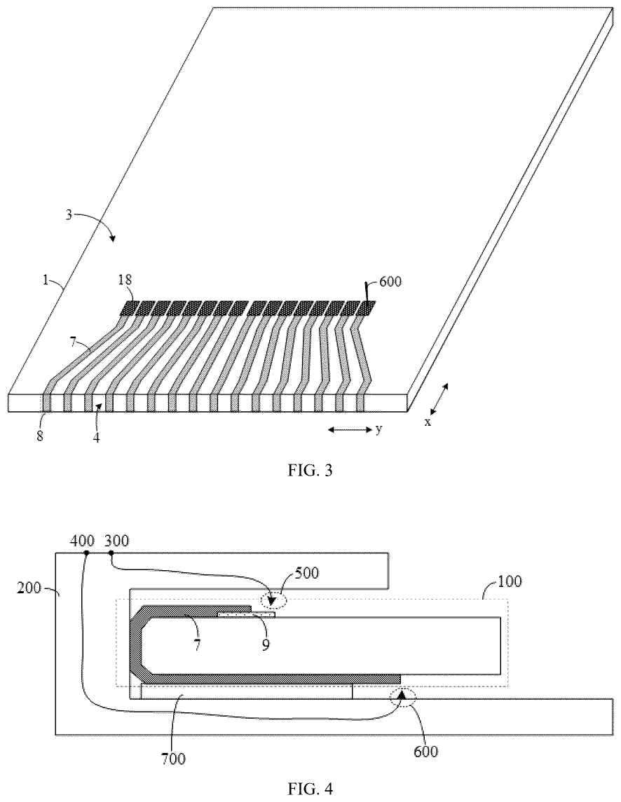

FIG. 1 is a schematic structural diagram of a display panel according to an embodiment of the present disclosure. FIG. 2 is a schematic diagram of a front surface of a display panel according to an embodiment of the present disclosure. FIG. 3 is a schematic diagram of a back surface of a display panel according to an embodiment of the present disclosure. As shown in FIG. 1 to FIG. 3, a display panel according to an embodiment of the present disclosure includes a substrate 1 including a first surface 2 and a second surface 3 that are opposite to each other, and a first side surface 4 connected to and between the first surface 2 and the second surface 3. The first surface 2 and the second surface 3 are opposite to each other in a thickness direction of the display panel. The first surface 2 is a surface of the substrate 1 adjacent to a light-emitting side of the display panel, that is, the front surface of the substrate 1, and the second surface 3 is a surface of the substrate 1 away from the light emitting side of the display panel, that is, the back surface of the substrate 1.

The display panel further includes signal lines 5 and connection electrodes 6 that are all located on the first surface 2. The signal lines 5 may include a plurality of types of traces for driving display, such as data lines, power lines, reset lines, etc. The connection electrode 6 is electrically connected to the signal line 5 and is adjacent to the first side surface 4.

The display panel further includes a connection line 7 electrically connected to the connection electrode 6, and the connection line 7 includes a side trace portion 8 located on the first side surface 4. In an example, the connection line 7 overlaps with the connection electrode 6 on the first surface 2, the connection line 7 extends from the first surface 2 and the first side surface 4 to the second surface 3, and is electrically connected to a driving structure such as a driving chip or a printed circuit board (not shown in the figures) on the second surface 3, to establish a signal transmission path between the driving structure and the signal line 5.

The connection electrodes 6 include a first connection electrode 9.

The first connection electrode 9 includes a first region 10 and a second region 11, and the first connection electrode 9 is connected to the connection line 7 in the first region 10. That is, the first connection electrode 9 is in contact connection to the connection line 7 in the first region 10, and is not in contact with the connection line 7 in the second region 11.

Additionally/Alternatively, a position where the first connection electrode 9 is connected to the connection line 7 is located in a non-middle region of the first connection electrode 9. That is, the position where the first connection electrode 9 is connected to the connection line 7 deviates from a central axis of the first connection electrode 9. For example, referring to FIG. 1, a position where the first connection electrode 9 is connected to the connection line 7 deviates from the first connection electrode 9 to the left, so that a partial region of the right side of the first connection electrode 9 remains free of contact with the connection line 7. Alternatively, a position where the first connection electrode 9 is connected to the connection line 7 deviates from the first connection electrode 9 to the right, so that a partial region of the left side of the first connection electrode 9 remains free of contact with the connection line 7.

In an embodiment of the present disclosure, the connection electrode 6 includes a first connection electrode 9. Only a partial region of the first connection electrode 9 is configured to be overlapped with the connection line 7, and another partial region of the first connection electrode 9 remains unoccupied. This unoccupied region is configured to provide a contact point for a probe when detecting the connection line.

FIG. 4 is a schematic diagram of a detection of a display panel according to an embodiment of the present disclosure. In combination with FIG. 2 to FIG. 4, when detecting the connection status of the connection line, the display panel 100 is firstly placed in a detection fixture 200. The detection fixture 200 has a first detection point 300, a second detection point 400, a first probe 500 that is electrically connected to the first detection point 300, and a second probe 600 that is electrically connected to the second detection point 400. Then, the first probe 500 is inserted into the second region 11 of the first connection electrode 9, and a detection voltage is applied to the connection line 7 using the second probe 600, so as to determine whether the connection state of the connection line 7 is normal according to the information such as the resistance between the first detection point 300 and the second detection point 400.

By adopting the display panel according to the embodiments of the present disclosure, the second region 11 of the first connection electrode 9 provides a contact point for the probe. When detecting the connection status of the connection line, the probe is inserted into the second region 11 of the first connection electrode 9, so as to detect the connection status of the connection line 7 corresponding to the first connection electrode 9. This structure can implement independent detection on the connection lines 7, and accurately obtain the connection status of each connection line 7, so as to specifically remedy the connection line 7 with connection problems, so that the display panel can have a better detection effect. Further, due to such a structure, the probe does not affect the connection line 7 during the detection, thereby preventing the connection line 7 from being pierced by the probe and thus from affecting the reliability of the connection of the connection line 7 to the first connection electrode 9.

Further, when detecting this structure, the display panel is probed on both sides. In combination with FIG. 4, the display panel is directly placed in the detection fixture with the front surface facing upwards. The first probe 500 is probed on the front surface, and the second probe 600 is probed on the back surface. The display panel does not need to be turned over with the back surface facing upwards, so as to avoid structural damage caused by the turning-over process.

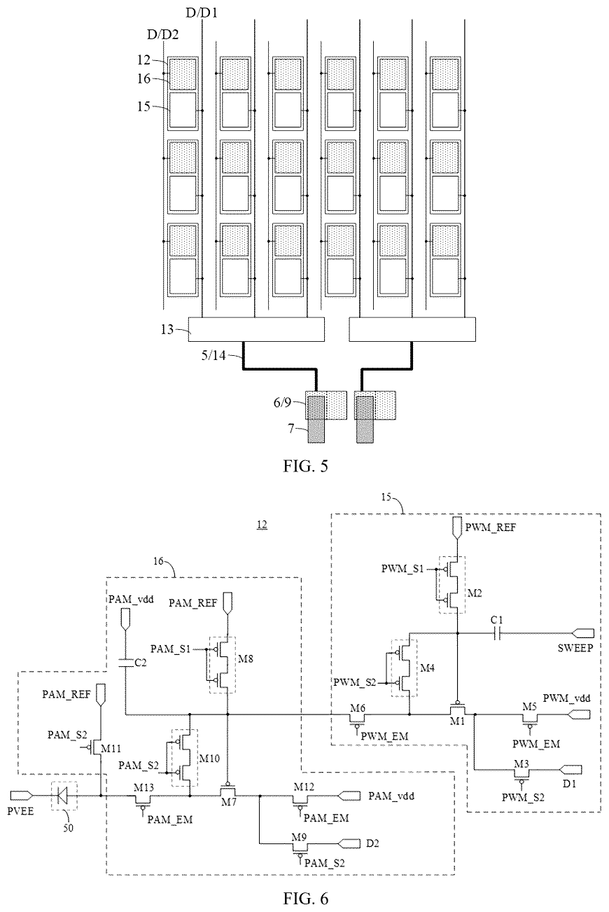

FIG. 5 is another schematic structural diagram of a display panel according to an embodiment of the present disclosure. In a feasible implementation, as shown in FIG. 5, the display panel further includes a pixel circuit 12 and a data line D. The data line D is electrically connected to the pixel circuit 12 and is configured to provide a data voltage to the pixel circuit 12.

The display panel further includes a plurality of gating units 13. The gating unit 13 includes an input terminal and output terminals. The input terminal is electrically connected to a source signal line 14. The output terminals are electrically connected to the data lines D, respectively. In an example, the gating unit 13 includes gating transistors. The gating transistors has gates connected to control lines, respectively, first electrodes electrically connected to a same source signal line 14, and second electrodes electrically connected to data lines D, respectively. During a driving process, the control lines provide enable levels in a time-division manner, and control the gating switches in the gating unit 13 to be turned on in a time-division manner, so as to transmit data signals in the source signal line 14 to the connected data lines D in a time-division manner.

The signal lines 5 include a source signal line 14, and at least part of the first connection electrodes 9 is electrically connected to the source signal line 14.

The display panel adopts a gating design for the data lines D, thereby greatly reducing the number of the connection electrodes 6 required to be arranged in the display panel. For example, the display panel has 720 data lines D, and the 720 data lines D originally need to be correspondingly provided with 720 connection electrodes 6. However, after introducing a one-to-three gating design, only 240 connection electrodes need to be provided for 240 source signal lines 14, thereby greatly reducing the number of connection electrodes 6 in the display panel.

The number of connection electrodes 6 is reduced, releasing a large part of space. This part of space can be used to widen the connection electrodes 6, so that the connection electrodes 6 will have an independent connection line overlapping region (the first region 19) and an independent probe contact region (the second region 11), that is, more connection electrodes 6 can be used as the first connection electrodes 9, thereby realizing independent detection of the connection lines 7. In other words, the number of the connection electrodes 6 is greatly reduced, the size of the first connection electrode 9 can be designed to be larger, and the first connection electrode 9 has a wider second region 11 to contact the probe, thereby reducing the difficulty of probe alignment and further reducing the design and manufacturing difficulty of the detection fixture.

Further, referring to FIG. 5 again, the pixel circuit 12 includes a pulse width modulation (PWM) module 15 and a pulse amplitude modulation (PAM) module 16. Correspondingly, the data line D includes a first data line D1 electrically connected to the pulse width modulation module 15 and a second data line D2 electrically connected to the pulse amplitude modulation module 16.

The pulse width modulation module 15 is configured to implement brightness adjustment by changing a duty cycle of a pulse signal, and the pulse amplitude modulation module 16 is configured to implement brightness adjustment by changing an amplitude of the pulse signal. The pixel circuit 12 adopts a PWM+PAM design to realize more precise brightness adjustment, so that the display panel can achieve more accurate color performance.

The first data line D1 is electrically connected to the gating unit 13.

In a related design, the first data line D1 corresponding to the pulse width modulation module 15 is directly driven by a driving chip, that is, each first data line D1 needs to correspond to one connection electrode 6, and is then connected to the driving chip through the connection line 7. Due to the higher resolution of the current display panel, there are a large number of the first data lines D1, for example, up to more than 1000 first data lines D1, resulting in a large number of the connection electrodes 6.

In an embodiment of the present disclosure, the first data line D1 is electrically connected to the gating unit 13, and a gating design is adopted for the first data line D1 to greatly reduce the number of the connection electrodes 6 in the display panel, thereby releasing more space to meet widening requirements of the connection electrodes 6, so that a larger number of connection electrodes 6 can be widened, or the connection electrodes 6 can reach a larger widening degree, and have a larger area to contact the probe.

FIG. 6 is a schematic diagram of a circuit structure of a pixel circuit according to an embodiment of the present disclosure. The circuit structure of the pixel circuit 12 is schematically described below by taking the structure shown in FIG. 6 as an example.

The pixel circuit 12 includes a pulse width modulation module 15 and a pulse amplitude modulation module 16.

The pulse width modulation module 15 may include: a first driving transistor M1, a first gate reset transistor M2, a first data writing transistor M3, a first compensation transistor M4, a first capacitor C1, a first light emitting control transistor M5, and a second light emitting control transistor M6.

The first gate reset transistor M2 has a gate electrically connected to a first scan line PWM-S1, a first electrode electrically connected to a first reset signal line PWM-REF, and a second electrode electrically connected to a gate of the first driving transistor M1.

The first data writing transistor M3 has a gate electrically connected to a second scan line PWM-S2, a first electrode electrically connected to a first data line D1, and a second electrode electrically connected to a first electrode of the first driving transistor M1.

The first compensation transistor M4 has a gate electrically connected to the second scan line PWM-S2, a first electrode electrically connected to a second electrode of the first driving transistor M1, and a second electrode electrically connected to the gate of the first driving transistor M1.

The first capacitor C1 has a first electrode plate electrically connected to a swept-frequency signal line SWEEP, and a second electrode plate electrically connected to the gate of the first driving transistor M1.

The first light emitting control transistor M5 has a gate electrically connected to a first light emitting control signal line PWM-EM, a first electrode electrically connected to a first fixed-potential signal line PWM-vdd, and a second electrode electrically connected to the first electrode of the first driving transistor M1.

The second light emitting control transistor M6 has a gate electrically connected to the first light emitting control signal line PWM-EM, and a first electrode electrically connected to the second electrode of the first driving transistor M1.

The pulse amplitude modulation module 16 may include: a second driving transistor M7, a second gate reset transistor M8, a second data writing transistor M9, a second compensation transistor M10, an anode reset transistor M11, a third light emitting control transistor M12, a fourth light emitting control transistor M13, and a second capacitor C2.

The second driving transistor M7 has a gate electrically connected to the second electrode of the second light emitting control transistor M6.

The second gate reset transistor M8 has a gate electrically connected to a third scan line PAM-S1, a first electrode electrically connected to a second reset signal line PAM-REF, and a second electrode electrically connected to the gate of the second driving transistor M7.

The second data writing transistor M9 has a gate electrically connected to a fourth scan line PAM-S2, a first electrode electrically connected to a second data line D2, and a second electrode electrically connected to a first electrode of the second driving transistor M7.

The second compensation transistor M10 has a gate electrically connected to the fourth scan line PAM-S2, a first electrode electrically connected to a second electrode of the second driving transistor M7, and a second electrode electrically connected to the gate of the second driving transistor M7.

The anode reset transistor M11 has a gate electrically connected to the fourth scan line PAM-S2, a first electrode electrically connected to the second reset signal line PAM-REF, and a second electrode electrically connected to a light emitting element 50.

The third light emitting control transistor M12 has a gate electrically connected to the second light emitting control transistor PAM-EM, a first electrode electrically connected to a second fixed-potential signal line PAM-vdd, and a second electrode electrically connected to the first electrode of the second driving transistor M7.

The fourth light emitting control transistor M13 has a gate electrically connected to the second light emitting control transistor PAM-EM, a first electrode electrically connected to the second electrode of the second driving transistor M7, and a second electrode electrically connected to the light emitting element 50.

The second capacitor C2 has a first electrode plate electrically connected to the second fixed-potential signal line PAM-vdd, and a second electrode plate electrically connected to the gate of the second driving transistor M7.

It should be noted that FIG. 6 is merely a schematic diagram of a circuit structure of the pixel circuit 12. In other alternative embodiments of the present disclosure, the pixel circuit 12 may also adopt other circuit structures.

In a feasible implementation, referring to FIG. 1, the first side surface 4 is located on a side of the display panel in a first direction x. The first region 10 and the second region 11 in the first connection electrode 9 are arranged along a second direction y, and the second direction y intersects with the first direction x. That is, the first side surface 4 is located on a side of the display panel in the longitudinal direction, and the first region 10 and the second region 11 in the first connection electrode 9 are arranged laterally.

Referring to FIG. 1, the connection electrode 6 includes a first side and a second side in the first direction x. An end of the signal line 5 extends from the first side of the connection electrode 6 to be connected to the connection electrode 6, and the connection line 7 is led out from the second side of the connection electrode 6 and extends to the first side surface 4. In the first connection electrode 9, the first region 10 and the second region 11 are arranged along the second direction y. A position of the second region 11 does not conflict with an end position of the signal line 5 and a leading-out position of the connection line 7, making it easier to contact the probe.

It should be noted that a boundary edge between the first side surface and the first surface can be seen in a part of the top view.

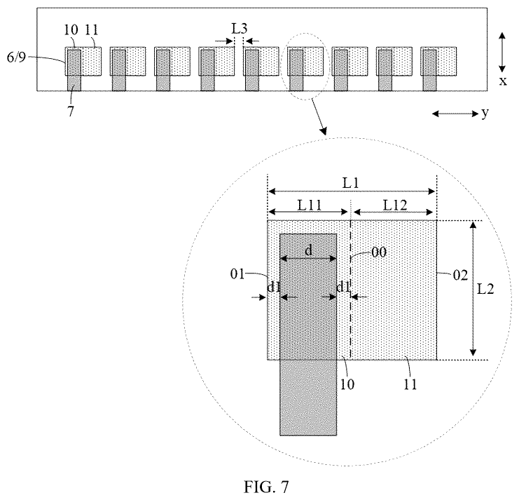

FIG. 7 is a schematic structural diagram of a connection electrode 6 according to an embodiment of the present disclosure. In a feasible implementation, as shown in FIG. 7, a length of the first connection electrode 9 in the second direction y is L1, and a length of a portion of the connection line 7 located on the first surface 2 in the second direction y is d, where L1≥1.5×d. For example, L1 is at least twice d.

And/or, in the first connection electrode 9, a length L12 of the second region 11 in the second direction y is greater than or equal to a length L11 of the first region 10 in the second direction y.

The length of the first region 10 and the length of the second region 11 in the second direction y are explained as follows:
Referring to FIG. 7, the first connection electrode 9 includes a first edge 01 and a second edge 02 that are opposite to each other in the second direction y. The first edge 01 is an edge of the first region 10, and a distance between the connection line 7 and the first edge 01 is d1.

A boundary line 00 is formed between the first region 10 and the second region 11. It is understandable that, the boundary line 00 does not actually exist, but is a virtual line for dividing the positions of the first region 10 and the second region 11. A distance between the boundary line 00 and the connection line 7 is also d1.

It is understandable that, a distance from the boundary line 00 to an outer edge of a side of the first region 10 away from the connection line 7 is greater than or equal to the width of the connection line in the second direction y.

A distance between the boundary line 00 and the first edge 01 may be regarded as a length L11 of the first sub-region in the second direction y, and a distance between the boundary line 00 and the second edge 02 may be regarded as a length L12 of the second sub-region in the second direction y.

When the first connection electrode 9 satisfies the above size design, the first connection electrode 9 may be considered to be widened by at least twice the original size of the connection electrode. The second region in the first connection electrode 9 has a larger transverse dimension, and has a larger probe contact area, which can reduce the alignment difficulty of the probe. Such design is more applicable to the panel structure having the aforementioned gating unit 13. In such a panel structure having a gating design, only a small number of the connection electrodes 6 are provided, making it easier for the first connection electrode 9 to meet the above size design requirements.

In an embodiment, referring to FIG. 7, a length of the first connection electrode 9 in the second direction y is L1, and L1>3 μm.

The line width of the connection line 7 may be 2 μm or more, and L1>3 μm. On the premise of ensuring a complete overlapping width with the connection line 7, a blank area with a sufficient width can be reserved as the second region 11, to provide a sufficient contact point for the probe, thereby reducing the alignment difficulty of the probe, and avoiding damage to the connection line 7 caused by the inaccurate alignment of the probe.

In an embodiment of the present disclosure, a specific value of L1 may be related to an actual line width of the connection line 7. As described above, L1 may be at least 1.5 times the line width d of the connection line 7. For example, when the actual line width of the connection line 7 is 30 μm, L1 may be designed to be 54 μm or more.

In an embodiment, referring to FIG. 7, a length of the first connection electrode 9 in the second direction y is L1, and a length of the first connection electrode 9 in the first direction

$$x is L 2 , \frac{L 1}{L 2} \geq 1.2 .$$

When a ratio of a transverse dimension to a longitudinal dimension of the first connection electrode 9 satisfies the above range, the first connection electrode 9 has a larger transverse dimension, and the first connection electrode 9 has a probe contact area with a sufficient area, reducing the alignment difficulty of the probe and avoiding damage to the connection line 7 caused by the inaccurate alignment of the probe.

In an embodiment of the present disclosure, a length L2 of the first connection electrode 9 in the first direction x may be greater than 5 μm, so that the first connection electrode 9 has a sufficient overlapping length with the connection line 7 in the first direction x, to ensure the connection strength. A specific value of L2 may be related to an accommodating space that the display panel can provide for the connection electrode 6 at the lower edge. In the first direction x, if there is enough space at the lower edge of the display panel to accommodate the connection electrode 6, the length L2 of the first connection electrode 9 in the first direction x may reach tens of microns or hundreds of microns. For example, L2 may be 100 μm.

Further, referring to FIG. 7, a spacing L3 between adjacent connection electrodes 6 may be greater than 3 μm, so as to ensure a sufficient spacing between adjacent connection electrodes 6, thereby avoiding short-circuiting between the connection line 7 and adjacent connection electrodes 6 caused by factors such as process errors, and avoiding a probe being inserted into adjacent connection electrodes 6 caused by factors such as alignment accuracy. A specific value of L3 may be related to the number of the connection electrodes 6. When the number of the connection electrodes 6 is smaller, L3 may be larger, for example, up to tens of microns, such as 50 μm. When the number of the connection electrodes 6 is larger, L3 may be smaller.

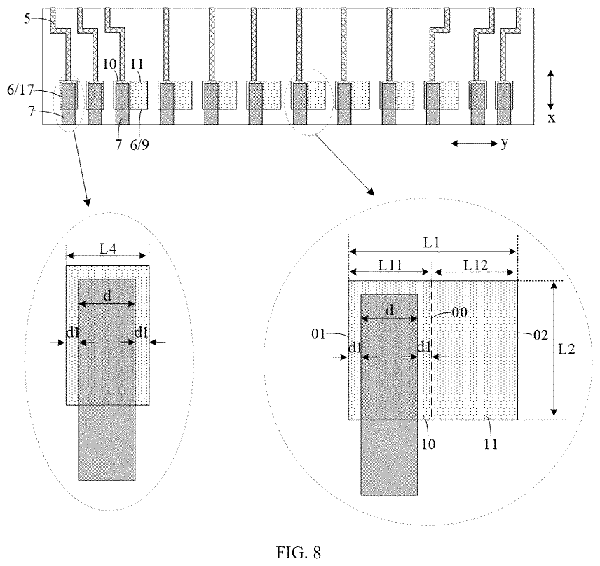

FIG. 8 is another schematic structural diagram of a connection electrode 6 according to an embodiment of the present disclosure. In a feasible implementation, as shown in FIG. 8, the connection electrode 6 further includes a second connection electrode 17, and a length of the second connection electrode 17 in the second direction y is less than a length of the first connection electrode 9 in the second direction y.

Exemplarily, in an embodiment, the second connection electrode 17 is a connection electrode having an original size, without widening. That is, referring to FIG. 8, in the second direction y, two opposing edges of the second connection electrode 17 are each spaced from the connection line 7 by a distance of d1.

In an embodiment, only the connection electrodes 6 corresponding to some signal lines 5 for transmitting more important signals may be designed to be widened, so as to separately detect the connection lines 7 corresponding to these connection electrodes 6, and to ensure the transmission reliability of the important signals. Further, the connection status of the connection line 7 corresponding to the second connection electrode 17 can be estimated according to the connection status of these connection lines 7.

Such configuration can widen only some of the connection electrodes 6, that is, only some of the connection electrodes 6 are used as the first connection electrodes 9, which can alleviate the burden that the overall connection electrodes 6 occupies the lateral space.

In an embodiment, a length of the second connection electrode 17 in the second direction y is L4, and a length of the first connection electrode 9 in the second direction y is L1, L1≥1.5×L4. For example, L1 is at least twice L4.

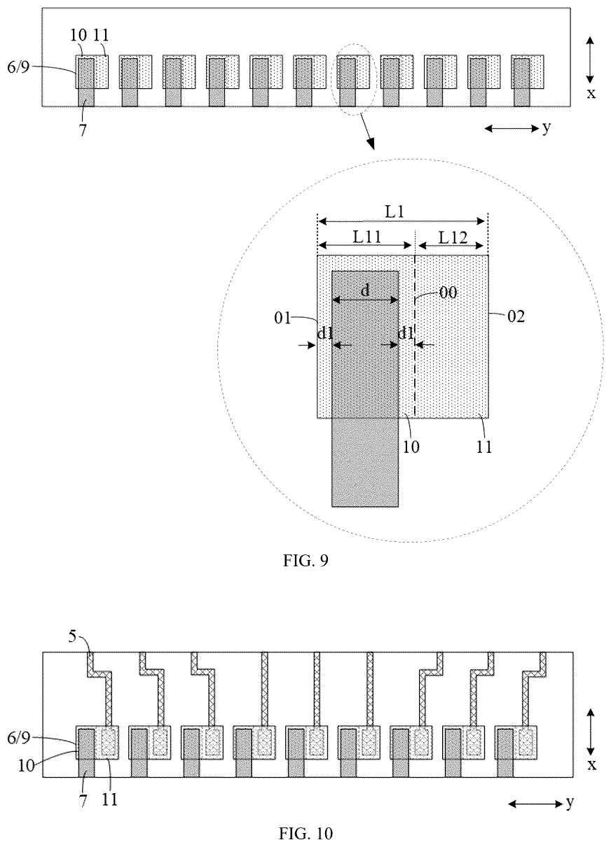

FIG. 9 is another schematic structural diagram of a connection electrode 6 according to an embodiment of the present disclosure. Alternatively, in another feasible implementation, as shown in FIG. 9, a length L12 of the second region 11 in the second direction y is less than a length L11 of the first region 10 in the second direction y, and/or the length L12 of the second region 11 in the second direction y is less than a length d of a part of the connection line 7 located on the first surface 2 in the second direction y.

The explanation of the lengths of the first region 10 and the second region 11 in the second direction y has been described in the above embodiments, and will not be repeated herein.

In the first connection electrode 9 of this structure, the second region 11 is narrower. On the premise that the second region 11 can meet the normal contact with the probe, a slightly narrower design can alleviate the burden that the overall connection electrode 6 occupies lateral space. This design can be more suitable for a panel structure with a larger number of connection electrodes 6.

FIG. 10 is another schematic structural diagram of a display panel according to an embodiment of the present disclosure. In a feasible implementation, as shown in FIG. 10, in a signal line 5 electrically connected to the first connection electrode 9, an end of the signal line 5 is connected to the first connection electrode 9 in the second region 11.

The first connection electrode 9 is padded with the signal line 5 in the second region 11, which can improve the structural support force of the first connection electrode 9 and improve the strength when the probe is pressed. Further, in this structure, the detection point during detection starts directly from the end of the signal line 5, avoiding the overlapping region between the first connection electrode 9 and the connection line 7, so as to provide the detection status of the signal line 5 more directly.

In a feasible implementation, referring to FIG. 3, the display panel further includes a bonding electrode 18. The bonding electrode 18 is located on the second surface 3 and electrically connected to the connection line 7. The bonding electrode 18 is further configured to be connected to a pin of a driving structure such as a driving chip or a printed circuit board.

In a detection manner, in combination with FIG. 3 and FIG. 4, when detecting the connection status of the connection line, the second probe 600 of the detection fixture 200 is inserted into the bonding electrode 18, and the second probe 600 applies a detection voltage to the connection line 7 through the bonding electrode 18.

However, considering that directly inserting the second probe 600 into the bonding electrode 18 may cause damage to the bonding electrode 18, thereby affecting the subsequent bonding of the bonding electrode 18 with the driving structure.

In view of this, in a feasible implementation, an embodiment of the present disclosure further provide that some detection electrodes electrically connected to the bonding electrode 18 may be added.

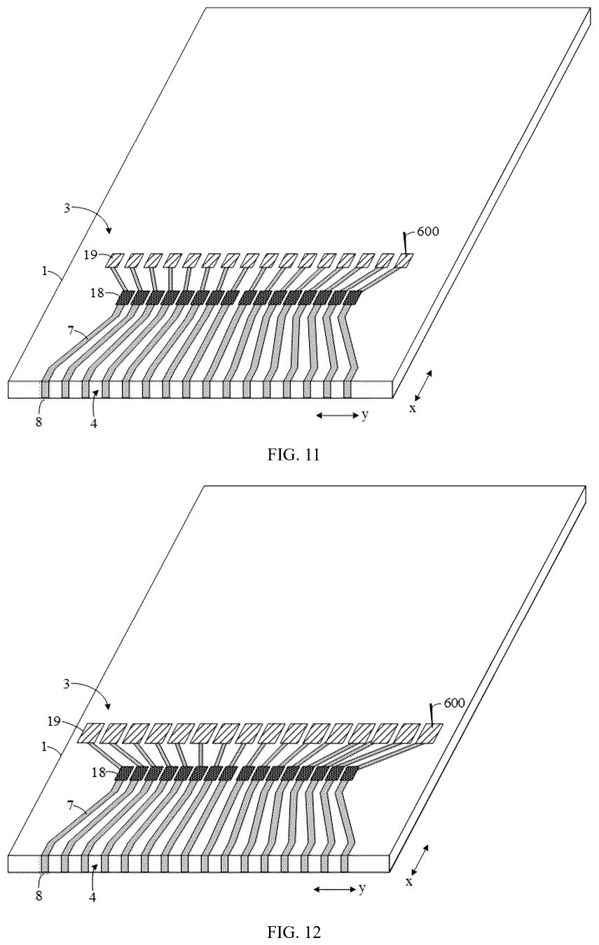

FIG. 11 is another schematic diagram of a back surface of a display panel according to an embodiment of the present disclosure. FIG. 12 is another schematic diagram of a back surface of a display panel according to an embodiment of the present disclosure. As shown in FIG. 11 and FIG. 12, the display panel further includes a detection electrode 19 that is located on the second surface 3 and electrically connected to the bonding electrode 18. The detection electrode 19 is not connected to the pin of the driving structure, and is configured to contact the probe during detection.

Based on the above structure, in the detection process, the second probe 600 of the detection fixture 200 may be inserted into the detection electrode 19, and a detection voltage is applied to the connection line 7 through the detection electrode 19. In this way, the probe does not need to contact the bonding electrode 18, and the reliability of the connection to the driving structure will not be affected by the damage of the bonding electrode 18.

Further, since the detection electrode 19 is not connected to the pin of the driving structure, the design parameters of the detection electrode 19 are not limited by design parameters of the pin of the driving structure, which are more flexible. For example, referring to FIG. 11 and FIG. 12 again, a distance between adjacent detection electrodes 19 is greater than a distance between adjacent bonding electrodes 18, and/or an area of the detection electrode 19 is greater than an area of the bonding electrode 18, so as to reduce the alignment difficulty of the second probe 600, and further reduce the design and manufacturing difficulty of the detection fixture.

In a feasible implementation, referring to FIG. 11 and FIG. 12 again, the detection electrode 19 is located at a side of the bonding electrode 18 away from the first side surface 4, so as to avoid a conflict between the detection electrode 19 and the wiring position of the connection line 7, and to avoid a conflict between the traces connected to and between the detection electrode 19 and the bonding electrode 18 and the wiring position of the connection line 7.

FIG. 13 is another schematic diagram of a back surface of a display panel according to an embodiment of the present disclosure. Alternatively, in another feasible implementation, as shown in FIG. 13, the display panel further includes a bonding electrode 18 that is located on the second surface 3 and electrically connected to the connection line 7. The bonding electrode 18 includes a third region 20 and a fourth region 21. The bonding electrode 18 is connected to the pin of the driving structure in the third region 20.

In such a structure, the bonding electrode 18 is used to contact the pin of the driving structure only in a part of the region, and another part of the region remains unoccupied. This unoccupied region is configured to provide a contact point for a probe when detecting the connection line. In the detection process, the second probe 600 of the detection fixture 200 is inserted into the fourth region 21 of the bonding electrode 18, and the second probe 600 does not contact the position connected to the pin of the driving structure, so as to avoid affecting the reliability of the connection between the bonding electrode 18 and the driving structure.

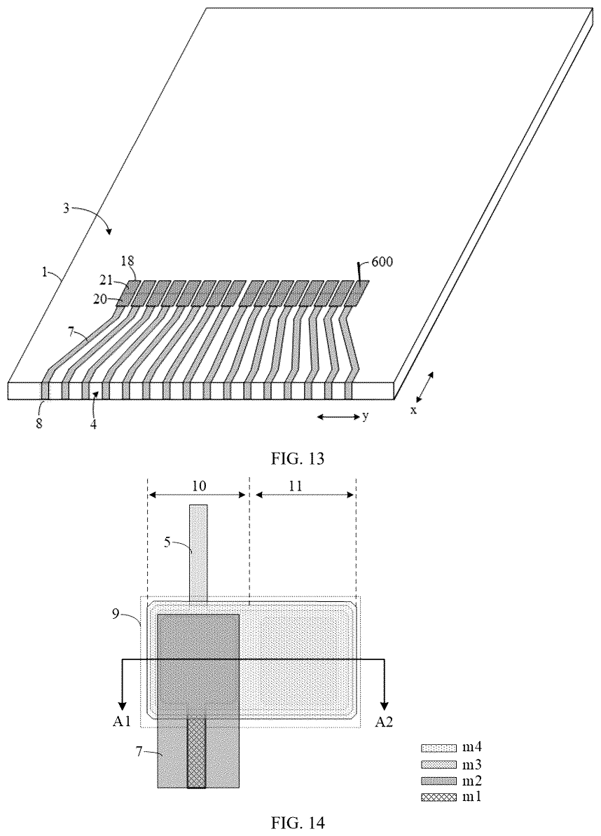

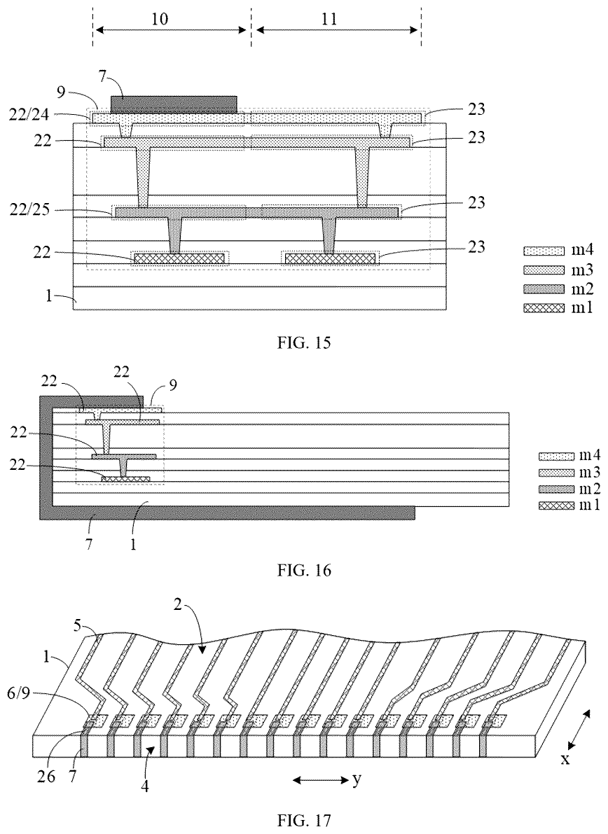

FIG. 14 is a top view of a first connection electrode 9 according to an embodiment of the present disclosure, FIG. 15 is a cross-sectional view along A1-A2 shown in FIG. 14, and FIG. 16 is a cross-sectional view of a display panel according to an embodiment of the present disclosure. In a feasible implementation, as shown in FIG. 14 to FIG. 16, the first connection electrode 9 includes at least two first metal portions 22 that are stacked in the first region 10, and adjacent first metal portions 22 are electrically connected through a via hole. The first connection electrode 9 includes at least two second metal portions 23 that are stacked in the second region 11, and adjacent second metal portions 23 are electrically connected through a via hole. The at least two first metal portions 22 are connected to the second metal portions 23 in the same layer, respectively.

For example, the display panel includes a first metal layer m1, a second metal layer m2, a third metal layer m3 and a fourth metal layer m4 that are stacked in a direction away from the substrate 1. The first connection electrode 9 includes four first metal portions 22 in the first region 10, and the four first metal portions 22 are located in the first metal layer m1, the second metal layer m2, the third metal layer m3 and the fourth metal layer m4, respectively. The first connection electrode 9 includes four second metal portions 23 that are stacked in the second region 11, and the four second metal portions 23 are located in the first metal layer m1, the second metal layer m2, the third metal layer m3 and the fourth metal layer m4, respectively.

Theoretically, the first connection electrode 9 is provided with only one second metal portion 23 in the second region 11, and the second metal portion 23 is connected to the first connection portion, so that the second region 11 and the connection line 7 are in a connection relationship, thereby enabling the second region 11 to assume a detection function.

However, in an embodiment of the present disclosure, the first connection electrode 9 includes second metal portions 23 in the second region 11, and at least two second metal portions 23 are in communication with the first metal portion 22 in the same layer. Such arrangement can, on the one hand, increase the connection strength between the metals inside the first connection electrode 9, and on the other hand, reduce the overall load of the first connection electrode 9.

Further, referring to FIG. 14 and FIG. 15 again, the first metal portion 22 includes a first metal sub-portion 24, and the first metal sub-portion 24 is the uppermost metal portion in the first connection electrode 9 and may be located in the fourth metal layer m4. The first metal sub-portion 24 overlaps with the connection line 7. The first metal sub-portion 24 is connected to the second metal portion 23 in the same layer as the first metal sub-portion 24, so that the first region 10 and the second region 11 of the uppermost metal are connected to each other as a whole in the first connection electrode 9.

The first metal portion 22 includes a second metal sub-portion 25. The second metal sub-portion 25 is in a same layer as the signal line 5 electrically connected to the first connection electrode 9 in which the second metal sub-portion 25 is located, and the second metal sub-portion 25 may be located in the second metal layer m2. The second metal sub-portion 25 is connected to the second metal portion 23 in the same layer as the second metal sub-portion 25, so that the first region 10 and the second region 11 of the metal in the same layer as the signal line 5 are connected to each other as a whole in the first connection electrode 9, thereby reducing the load of the metal and improving the signal transmission quality.

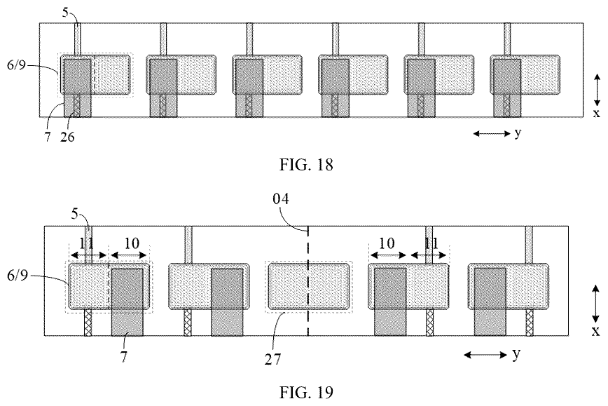

FIG. 17 is another schematic structural diagram of a front surface of a display panel according to an embodiment of the present disclosure. FIG. 18 is another schematic structural diagram of a display panel according to an embodiment of the present disclosure. In a feasible implementation, as shown in FIG. 17 and FIG. 18, the display panel further includes a first trace 26. The first trace 26 is located on the first surface 2 and electrically connected to the connection electrode 6. Further, the first trace 26 is located at a side of the connection electrode 6 adjacent to the first side surface 4, and an end of the first trace 26 is exposed to an edge of the display panel.

In first connection electrode 9 is adjacent to the first trace 26, and the first trace 26 is located at a side of the connection electrode 6 adjacent to the first side surface 4 in the first region 10.

Regarding the first trace 26, in one case, in the manufacturing process of the display panel, the connection electrode 6 leads out a trace below to extend to the outside of the cutting line for introducing an external signal to complete some tests in the manufacturing process. After the tests are completed, the display panel is cut along the cutting line, the portion, located outside the cutting line, of the led-out part of trace is cut off, the portion, located inside the cutting line, of the led-out part of trace is retained in the display panel, and the retained part is the above first trace 26.

The first trace 26 is located at a side of the first connection electrode 9 adjacent to the first side surface 4 in the first region 10, and the connection line 7 contacts an end of the first trace 26 when extending toward the first side surface 4, thereby improving the connection strength between the connection line 7 and the first connection electrode 9.

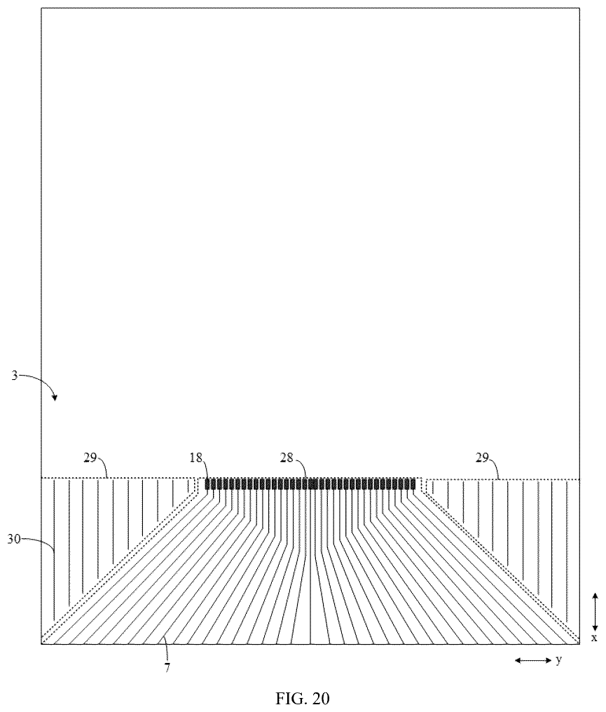

FIG. 19 is another schematic structural diagram of a connection electrode 6 according to an embodiment of the present disclosure. In a feasible implementation, as shown in FIG. 19, the first side surface 4 is located at a side of the display panel in the first direction x.

The display panel has a first central axis 04 extending along the first direction x. In the first connection electrodes 9 located at both sides of the first central axis 04, the first regions 10 in the first connection electrodes 9 are all located at a side of the second region 11 adjacent to the first central axis 04, or the first regions 10 in the first connection electrodes 9 are all located at a side of the second region 11 away from the first central axis 04. At this time, the first connection electrodes 9 on both sides of the first central axis 04 are designed in left-right symmetry, which is more convenient and beautiful in design.

Further, referring to FIG. 19, the display panel may further include a dummy electrode 27, and the dummy electrode 27 and the connection electrode 5 are arranged along the second direction y. The dummy electrode 27, as a virtual pad, is not connected to the signal line 5, the first trace 26, and the connection line 7, so as to prevent an etching abnormality in the manufacturing process to ensure the stability of the manufacturing process. Further, the dummy electrode 27 can be located in the middle of the display panel and overlap with the first central axis 04, and the first connection electrode 9 on the left side and the first connection electrodes 9 on the right side of the dummy electrode 27 are designed symmetrically as described above, so that the distribution of the overall electrode at the lower edge of the display panel is more regular, and the trace distribution is also more beautiful.

FIG. 20 is another schematic diagram of a back surface of a display panel according to an embodiment of the present disclosure. In a feasible implementation, as shown in FIG. 20, the first side surface 4 is located at a side of the display panel in the first direction x.

The second surface 3 includes a fan-out region 28 and a non-fan-out region 29. A part of the connection line 7 located on the second surface 3 is located in the fan-out region 28, and the non-fan-out region 29 is located on at least one side of the fan-out region 28 in the second direction y. The second direction y intersects with the first direction x. The non-fan-out region 29 includes the second trace 30.

When extending from the first side surface 4 to the second surface 3, the connection lines 7 converge to the position of the bonding electrode 18 in the fan-out region 28. The connection lines 7 are just partially distributed on the second surface 3. Some second traces 30 are arranged in the blank region on a side of the fan-out region 28, the etching uniformity of this region can be improved by the second traces 30 in the manufacturing process.

In an embodiment, the second surface 3 includes one fan-out region 28 and two non-fan-out regions 29, and the two non-fan-out regions 29 are located at both sides of the fan-out region 28 in the second direction y, respectively.

Based on the same inventive concept, an embodiment of the present disclosure further provides a method for detecting a display panel, which is applied to the above display panel.

In combination with FIG. 1 to FIG. 4, the detection method includes: providing a detection fixture 200. The detection fixture 200 includes a first detection point 300, a second detection point 400, a first probe 500 electrically connected to a first detection point 300, and a second probe 600 electrically connected to a second detection point 400.

The detection fixture 200 has an accommodating space for carrying the display panel. The first probe 500 is a top probe located at an upper side of the accommodating space, and the second probe 600 is a bottom probe located at a lower side of the accommodating space.

The detection method further includes: the display panel 100 is placed with the front side facing upwards in the detection fixture, the first probe 500 is placed at a side of the first surface 2 and is in contact with the second region 11 of the first connection electrode 9, the second probe 600 is placed at a side of the second surface 3 and provides a detection voltage to the connection line 7, and the connection status of the connection line 7 is determined according to the resistance between the first detection point 300 and the second detection point 400.

By adopting the technical solution according to the embodiments of the present disclosure, the second region 11 of the first connection electrode 9 provides a contact point for the probe. When detecting the connection status of the connection line, the probe is inserted into the second region 11 of the first connection electrode 9, so as to detect the connection status of the connection line 7 corresponding to the first connection electrode 9. Such a structure can implement independent detection on the connection lines 7, and accurately obtain the connection status of each connection line 7, so as to specifically remedy any of the connection lines 7 that have connection problems, so that the display panel can have a better detection effect. Further, the probe does not affect the connection line 7 during the detection of this structure, thereby preventing the connection line 7 from being pierced by the probe and thus from affecting the reliability of the connection of the connection line 7 to the first connection electrode 9.

Further, when detecting this structure, the display panel is inserted with pins on both sides. In combination with FIG. 4, the display panel is directly placed in the detection fixture with the front surface facing upwards. The first probe 500 is probed on the front surface, and the second probe 600 is probed on the back surface. The display panel does not need to be turned over to with the back surface facing upwards, so as to avoid structural damage caused by the turning-over process.

Further, referring to FIG. 4, the detection fixture 200 may further include a flexible pad 700. When placed in the detection fixture 200, the display panel is placed on the flexible pad 700, thereby protecting the display panel from damage.

Further, in combination with FIG. 11 and FIG. 12, the display panel further includes a bonding electrode 18 located on the second surface 3 and electrically connected to the connection line 7, and a detection electrode 19 located on the second surface 3 and electrically connected to the bonding electrode 18.

When the display panel is placed in the detection fixture, the second probe 600 is in contact with the detection electrode 19, and a detection voltage is applied to the connection line 7 through the detection electrode 19.

In this way, the probe does not need to contact the bonding electrode 18, so that the reliability of the connection to the driving structure will not be affected due to the damage of the bonding electrode 18.

Further, since the detection electrode 19 is not connected to the pin of the driving structure, design parameters of the detection electrode 19 are not limited by design parameters of the pin of the driving structure, and thus are more flexible, thereby reducing the difficulty of aligning the second probe 600, and reducing the design and manufacturing difficulty of the detection fixture 200.

Based on the same inventive concept, an embodiment of the present disclosure further provides a detection fixture for detecting the above display panel.

In combination with FIG. 2 to FIG. 4, the detection fixture 200 includes a first detection point 300, a second detection point 400, a first probe 500 electrically that is connected to the first detection point 300, and a second probe 600 that is electrically connected to the second detection point 400. The first probe 500 is configured to contact the second region 11 of the first connection electrode 9 in the display panel 100, and the second probe 600 is configured to apply a detection voltage to the connection line 7 in the display panel 100.

During the detection process, whether the connection state of the connection line 7 is normal or not can be determined according to information such as a resistance between the first detection point 300 and the second detection point 400.

In combination with the foregoing analysis, it can be seen that when the display panel 100 is detected using the detection fixture 200, the display panel is inserted with pins on both sides. The display panel is directly placed with the front side facing upwards in the detection fixture, the first probe 500 can be probed on the front surface, and the second probe 600 can be probed on the back surface. The display panel does not need to be turned over to with the back surface facing upwards, so as to avoid structural damage caused by the turning-over process.

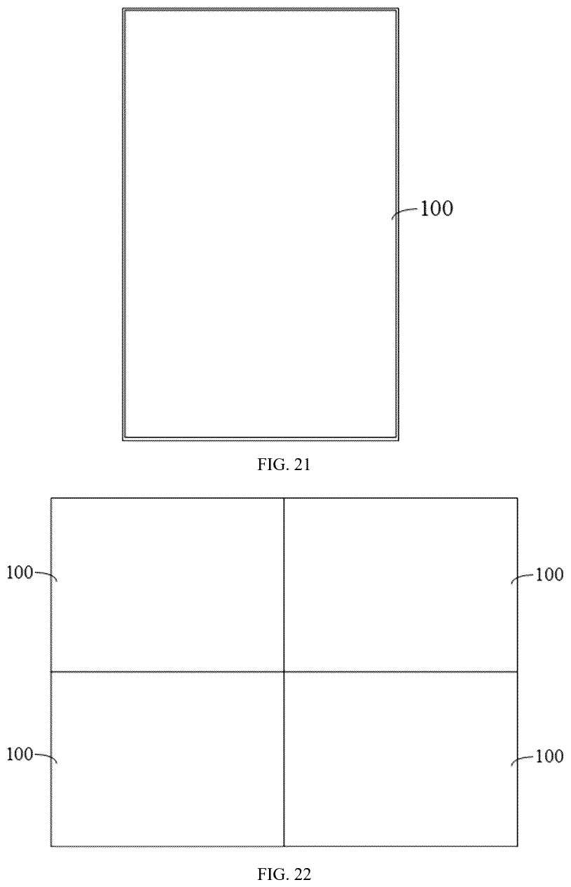

Based on the same inventive concept, an embodiment of the present disclosure further provides a display device. As shown in FIG. 21 and FIG. 22, FIG. 21 is a schematic structural diagram of a display device according to an embodiment of the present disclosure, and FIG. 22 is another schematic structural diagram of a display device according to an embodiment of the present disclosure. The display device includes the above display panel 100.

The display device according to the embodiments of the present disclosure may be an electronic device such as a mobile phone, a tablet computer, a notebook computer, an e-book, or a television, as shown in FIG. 21. Alternatively, the display device may be a spliced display device such as an outdoor large screen, as shown in FIG. 22, and the display device includes at least two display panels.

The above description merely illustrates some preferred embodiments of the present disclosure, but is not intended to limit the present disclosure, and any modification, equivalent substitution, improvement and the like made within a spirit and a principle of the present disclosure shall fall with the scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate comprising a first surface and a second surface that are opposite to each other, and a first side surface connected between the first surface and the second surface;
a signal line arranged on the first surface;
a connection electrode arranged on the first surface and electrically connected to the signal line; and
a connection line electrically connected to the connection electrode and comprising a side trace portion arranged on the first side surface;
wherein the connection electrode comprises a first connection electrode comprising a first region and a second region, and wherein the first connection electrode is connected to the connection line in the first region, and/or a position of the first connection electrode connected to the connection line is located in a non-middle region of the first connection electrode.

2. The display panel according to claim 1, further comprising:
a pixel circuit;
a plurality of data lines electrically connected to the pixel circuit; and
a plurality of gating units, wherein at least one gating unit comprises an input terminal electrically connected to a source signal line, and output terminals electrically connected to the plurality of data lines, respectively;
wherein the signal line comprises a source signal line, and at least part of first connection electrodes are electrically connected to the source signal line.

3. The display panel according to claim 2, wherein
the pixel circuit comprises a pulse width modulation module and a pulse amplitude modulation module, the data lines comprise a first data line electrically connected to the pulse width modulation module, and a second data line electrically connected to the pulse amplitude modulation module; and
the first data line is electrically connected to the at least one of the gating units.

4. The display panel according to claim 1, wherein
the first side surface is located at a side of the display panel in a first direction; and
in the first connection electrode, the first region and the second region are arranged along a second direction, and the second direction intersects with the first direction.

5. The display panel according to claim 4, wherein
a length of the first connection electrode in the second direction is L1, and a length of a part of the connection line located on the first surface in the second direction is d, wherein L1≥1.5×d; and/or in the first connection electrode, a length of the second region in the second direction is greater than or equal to a length of the first region in the second direction.

6. The display panel according to claim 4, wherein a length of the first connection electrode in the second direction is L1, wherein L1>3 μm.

7. The display panel according to claim 4, wherein
a length of the first connection electrode in the second direction is L1, and a length of the first connection electrode in the first direction is L2, where
$$\frac{L 1}{L 2} \geq 1.2 .$$

8. The display panel according to claim 4, wherein
the connection electrode further comprises a second connection electrode, and a length of the second connection electrode in the second direction is less than a length of the first connection electrode in the second direction.

9. The display panel according to claim 4, wherein
a length of the second region in the second direction is less than a length of the first region in the second direction; and/or
the length of the second region in the second direction is less than a length of a part of the connection line located on the first surface in the second direction.

10. The display panel according to claim 1, further comprising:
a bonding electrode located on the second surface and electrically connected to the connection line; and
a detection electrode located on the second surface and electrically connected to the bonding electrode.

11. The display panel according to claim 10, wherein
the detection electrode is located on a side of the bonding electrode away from the first side surface.

12. The display panel according to claim 10, wherein
a distance between adjacent detection electrodes is greater than a distance between adjacent bonding electrodes, and/or an area of the detection electrode is greater than an area of the bonding electrode.

13. The display panel according to claim 1, further comprising:
a bonding electrode located on the second surface and electrically connected to the connection line;
wherein the bonding electrode comprises a third region and a fourth region, and the bonding electrode is connected to a pin of a driving structure in the third region.

14. The display panel according to claim 1, wherein
the first connection electrode comprises at least two first metal portions that are stacked in the first region, and the first connection electrode comprises at least two second metal portions that are stacked in the second region, and wherein the at least two first metal portions are respectively connected to a respective one of the at least two second metal portions in a same layer as the at least two first metal portions.

15. The display panel according to claim 14, wherein
the first metal portion comprises a first metal sub-portion, the first metal sub-portion overlaps with the connection line, and the first metal sub-portion is connected to the second metal portion in a same layer as the first metal sub-portion; and
the first metal portion comprises a second metal sub-portion, the second metal sub-portion is in a same layer as the signal line electrically connected to the first connection electrode, and the second metal sub-portion is connected to the second metal portion in the same layer as the second metal sub-portion.

16. The display panel according to claim 1, further comprising:
a first trace located on the first surface and electrically connected to the connection electrode,
wherein the first trace is located at a side of the connection electrode adjacent to the first side surface, and an end of the first trace is exposed to an edge of the display panel; and
wherein the first connection electrode is adjacent to the first trace, and the first trace is located at a side of the connection electrode adjacent to the first side surface in the first region.

17. The display panel according to claim 1, wherein
the first side surface is located at a side of the display panel in a first direction;
the display panel has a first central axis extending in the first direction; and
in first connection electrodes located at both sides of the first central axis, first regions in the first connection electrodes are all located at a side of the second region adjacent to the first central axis, or the first regions in the first connection electrodes are all located at a side of the second region away from the first central axis.

18. The display panel according to claim 1, wherein
the first side surface is located at a side of the display panel in a first direction; and
the second surface comprises a fan-out region and a non-fan-out region, a part of the connection line located on the second surface is located in the fan-out region, the non-fan-out region is located on at least one side of the fan-out region in a second direction, the non-fan-out region comprises a second trace, and the second direction intersects with the first direction.

19. The display panel according to claim 1, wherein
in the signal line electrically connected to the first connection electrode, an end of the signal line is connected to the first connection electrode in the second region.

20. A method for a detecting display panel, applied to a display panel, wherein the display panel comprises:
a substrate comprising a first surface and a second surface that are opposite to each other, and a first side surface connected between the first surface and the second surface;
a signal line arranged on the first surface;
a connection electrode arranged on the first surface and electrically connected to the signal line; and
a connection line electrically connected to the connection electrode and comprising a side trace portion arranged on the first side surface;
wherein the connection electrode comprises a first connection electrode comprising a first region and a second region, and wherein the first connection electrode is connected to the connection line in the first region, and/or a position of the first connection electrode connected to the connection line is located in a non-middle region of the first connection electrode; and
wherein the method comprises:
providing a detection fixture, wherein the detection fixture comprises a first detection point, a second detection point, a first probe electrically connected to the first detection point, and a second probe electrically connected to the second detection point; and
placing the display panel with a front side facing upwards in the detection fixture, placing the first probe at a side of the first surface and in contact with the second region of the first connection electrode, placing the second probe at a side of the second surface and providing a detection voltage to the connection line, and determining a connection status of the connection line according to a resistance between the first detection point and the second detection point.

21. The method according to claim 20, wherein
the display panel further comprises a bonding electrode located on the second surface and electrically connected to the connection line, and a detection electrode located on the second surface and electrically connected to the bonding electrode; and
when the display panel is placed in the detection fixture, the second probe is in contact with the detection electrode, and the detection voltage is applied to the connection line through the detection electrode.

22. A detection fixture for detecting a display panel, wherein the display panel comprises:
a substrate comprising a first surface and a second surface that are opposite to each other, and a first side surface connected between the first surface and the second surface;
a signal line arranged on the first surface;
a connection electrode arranged on the first surface and electrically connected to the signal line; and
a connection line electrically connected to the connection electrode and comprising a side trace portion arranged on the first side surface;
wherein the connection electrode comprises a first connection electrode comprising a first region and a second region, and wherein the first connection electrode is connected to the connection line in the first region, and/or a position of the first connection electrode connected to the connection line is located in a non-middle region of the first connection electrode; and
wherein the detection fixture comprises:
a first detection point and a second detection point; and
a first probe electrically connected to the first detection point and a second probe electrically connected to the second detection point, wherein the first probe is configured to contact the second region of the first connection electrode in the display panel, and the second probe is configured to apply a detection voltage to the connection line in the display panel.
